(19) United States
(12) Patent Application Publication
(10) Pub. No.: US 2026/0164969 A1
(43) Pub. Date: Jun. 11, 2026

(54) ELECTRONIC DEVICE

(71) Applicant: Innolux Corporation, Miaoli County (TW)

(72) Inventors: Yi-Cheng Tsai, Miaoli County (TW); Yu-Wei Tu, Miaoli County (TW)

(73) Assignee: Innolux Corporation, Miaoli County (TW)

(21) Appl. No.: 19/389,079

(22) Filed: Nov. 14, 2025

Related U.S. Application Data
(60) Provisional application No. 63/729,467, filed on Dec. 9, 2024.

(30) Foreign Application Priority Data
Jun. 30, 2025 (CN) 202510895380.8

(51) Int. Cl. H10K 59/131; H10H 29/32; H10H 29/49; H10K 59/121

(52) U.S. Cl. CPC H10K 59/131; H10H 29/32; H10H 29/49; H10K 59/1213

(57) ABSTRACT

An electronic device includes a plurality of scan lines including first and second scan lines, a first scan transmission line, a second scan transmission line, at least one first conductive pattern electrically connected in parallel to at least one of the first scan transmission line and the first scan line, and having a first area, and at least one second conductive pattern electrically connected in parallel to at least one of the second scan transmission line and the second scan line, and having a second area. The first and second scan transmission lines cross the scan lines to form a plurality of first and second intersections, respectively. A length of the first scan transmission line is greater than a length of the second scan transmission line, and the first area is greater than the second area.

### CROSS-REFERENCE TO RELATED APPLICATION

This application claims the priority benefit of U.S. provisional application Ser. No. 63/729,467, filed on Dec. 9, 2024, and China application serial no. 202510895380.8, filed on Jun. 30, 2025. The entirety of each of the above-mentioned patent applications is hereby incorporated by reference herein and made a part of this specification.

### BACKGROUND

### Technical Field

The disclosure relates to an electronic device.

### Description of Related Art

With the advancement of technology, various electronic devices with a plurality of functions have been developed. Correspondingly, these electronic devices also have relatively complex circuit layouts. Taking display devices as an example, how to arrange circuits so that the signal lines of the display device have similar resistance-capacitance loadings (RC loading) and provide better luminance uniformity is an important issue.

### SUMMARY

The disclosure is directed to an electronic device.

In some embodiments of the disclosure, an electronic device includes a plurality of scan lines, a first scan transmission line, a second scan transmission line, at least one first conductive pattern, and at least one second conductive pattern. The plurality of scan lines include a first scan line and a second scan line. The first scan transmission line cross the plurality of scan lines to form a plurality of first intersections, and the plurality of first intersections include a first bridge portion where the first scan transmission line is electrically connected to the first scan line. The second scan transmission line cross the plurality of scan lines to form a plurality of second intersections, and the plurality of second intersections include a second bridge portion where the second scan transmission line is electrically connected to the second scan line. The at least one first conductive pattern is electrically connected in parallel to at least one of the first scan transmission line and the first scan line, and has a first area. The at least one second conductive pattern is electrically connected in parallel to at least one of the second scan transmission line and the second scan line, and has a second area. A length of the first scan transmission line is greater than a length of the second scan transmission line, and the first area is greater than the second area.

In other embodiments of the disclosure, an electronic device includes a plurality of scan lines, a first scan transmission line, and a second scan transmission line. The plurality of scan lines include a first scan line and a second scan line. The first scan transmission line cross the plurality of scan lines to form a plurality of first intersections, and include a first main line and a first extension line electrically connected to the first main line, where the plurality of first intersections include a first bridge portion where the first scan transmission line is electrically connected to the first scan line, and the first main line and the first extension line are respectively disposed on two different sides of the first bridge portion in a top view direction. The second scan transmission line cross the plurality of scan lines to form a plurality of second intersections, and include a second main line and a second extension line electrically connected to the second main line, where the plurality of second intersections include a second bridge portion where the second scan transmission line is electrically connected to the second scan line, and the second main line and the second extension line are respectively disposed on two different sides of the second bridge portion in a top view direction. A length of the first main line is greater than a length of the second main line, a length of the first extension line is less than or equal to a length of the second extension line, and a length of the first scan transmission line is different from a length of the second scan transmission line.

In still other embodiments of the disclosure, the electronic device includes a plurality of scan lines and a first scan transmission line. The plurality of scan lines include a first scan line. The first scan transmission line cross the plurality of scan lines to form a plurality of first intersections, and the plurality of first intersections include a first bridge portion where the first scan transmission line is electrically connected to the first scan line. The first scan line has different shapes disposed on two different sides of the first bridge portion in a top view direction.

### BRIEF DESCRIPTION OF THE DRAWINGS

FIG. 1A is a circuit schematic diagram of an electronic device according to the first embodiment of the disclosure.

FIG. 1B is an enlarged top view schematic diagram of a region R1 according to FIG. 1A.

FIG. 1C is a cross-sectional schematic diagram taken along line A1-A1′ according to FIG. 1B.

FIG. 1D is a cross-sectional schematic diagram taken along line A2-A2′ according to FIG. 1B.

FIG. 2A is a top view schematic diagram of the setting relationship between conductive patterns, scan lines, and scan transmission lines according to an embodiment of the disclosure.

FIG. 2B is a top view schematic diagram of the setting relationship between conductive patterns, scan lines, and scan transmission lines according to another embodiment of the disclosure.

FIG. 3 is a circuit schematic diagram of an electronic device according to the second embodiment of the disclosure.

FIG. 4A is a circuit schematic diagram of an electronic device according to the third embodiment of the disclosure.

FIG. 4B is an enlarged top view schematic diagram of a region R2 according to FIG. 4A.

FIG. 4C is a cross-sectional schematic diagram taken along line A3-A3′ according to FIG. 4B.

FIG. 5 is a circuit schematic diagram of an electronic device according to the fourth embodiment of the disclosure.

FIG. 6 is a circuit schematic diagram of an electronic device according to the fifth embodiment of the disclosure.

FIG. 7A is a circuit schematic diagram of an electronic device according to the sixth embodiment of the disclosure.

FIG. 7B is an enlarged top view schematic diagram of a region R3 according to FIG. 7A.

FIG. 8A is a circuit schematic diagram of an electronic device according to the seventh embodiment of the disclosure.

FIG. 8B is an enlarged top view schematic diagram of a region R4 according to FIG. 8A.

FIG. 9 is a schematic diagram of a method for luminance measurement of an electronic device according to an embodiment of the disclosure.

### DESCRIPTION OF THE EMBODIMENTS

The disclosure may be understood by referring to the following detailed description with reference to the accompanying drawings. It is noted that for comprehension of the reader and simplicity of the drawings, in the drawings provided in the disclosure, only a part of the electronic device is shown, and certain devices in the drawings are not necessarily drawn to actual scale. The quantity and the size of each device in the drawings are only schematic and exemplary and are not intended to limit the scope of protection provided in the disclosure. Moreover, relative dimensions, thickness, and positions of various layers, regions, and/or structures may be reduced or enlarged for clarity.

Throughout the specification and appended claims of the disclosure, certain terms are used to refer to specific components. People skilled in the art should understand that manufacturers of electronic devices may refer to the same elements under different names. The disclosure does not intend to distinguish devices with the same functions but different names. In the following specification and claims, the words “including”, “containing”, and “having” are open-ended words and therefore should be interpreted as “containing but not limited to . . . ”. Therefore, when the terms “including”, “containing”, and/or “having” are used in the description of the disclosure, the terminologies designate the presence of a corresponding feature, region, steps, operation, and/or element, but do not exclude the presence of one or more corresponding features, regions, steps, operations, and/or elements.

Directional terminologies mentioned herein, such as “top”, “bottom”, “front”, “back”, and so forth, refer to directions in the accompanying reference drawings. Accordingly, the directional terminologies provided herein serve to describe rather than limit the disclosure.

When a corresponding element is referred to as being “on another element,” the element may be directly on the other element or there may be another element between the two. On the other hand, when an element is referred to as being “directly on another element,” there is no element between the two. Also, when an element is referred to as being “on another element,” the two have a top-down relationship in the top view direction, and the element may be above or below the other element, and the top-down relationship depends on the orientation of the device.

The terminologies “about”, “equal to”, “equivalent to” or “same”, “substantially” or “approximately” are generally interpreted as being within 20% of a given value or range, or interpreted as being within 10%, 5%, 3%, 2%, 1%, or 0.5% of a given value or range.

The ordinal numbers used in the specification and claims, such as “first”, “second”, etc., are used to modify the elements, and they do not imply or represent that the element(s) have any previous ordinal numbers, nor do they represent the order of an element relative to another element, or the order of a manufacturing method. The use of these ordinal numbers is only used to clearly distinguish an element with a certain name from another element with the same name. The terms used in the claims and specification may not have to be the same, and accordingly, the first component provided in the specification may be the second component in the claims.

It should be understood that the following embodiments may replace, reorganize, and mix the features in different embodiments to complete other embodiments without departing from the spirit of the disclosure. As long as the features of the embodiments do not violate the spirit of the disclosure or conflict with each other, they may be mixed and matched as desired.

An electrical connection or coupling relationship described in the disclosure may refer to a direct connection or an indirect connection. In the case of the direct connection, end points of the elements on two circuits are directly connected or connected to each other by a conductor segment, and in the case of the indirect connection, there are other electronic components between the end points of the elements on the two circuits.

In the disclosure, measurement of thickness, length, width, height, distance and area may be obtained by optical microscope (OM), electron microscope (such as scanning electron microscope (SEM)) or other methods, but not limited thereto. In addition, certain errors between any two values or directions for comparison may be acceptable. If a first value is equal to a second value, it implies that there may be an error of about 10% between the first value and the second value. If a first direction is perpendicular to a second direction, an angle difference between the first direction and the second direction may be between 80 degrees and 100 degrees; if the first direction is parallel to the second direction, an angle difference between the first direction and the second direction may be between 0 degrees and 10 degrees.

The electronic device of the disclosure may be applied to display devices, automation equipment, computing devices, mechanical equipment, exposure devices, printing devices, three-dimensional printing devices, automotive devices, imaging devices, assembly devices, backlight devices, antenna devices, light-emitting devices, sensing devices, medical devices, touch devices, or tiling devices. The electronic devices comprise rollable, bendable, or flexible electronic devices. The display device may be a non-self-luminous display device, a self-luminous display device, a transparent display device, a mirror display device, a transflective display device, or a reflective display device. The electronic device may comprise, e.g., diodes, liquid crystal, light emitting diodes (LED), quantum dots (QD), fluorescence, phosphor, other suitable display media, or combinations thereof. The sensing device may be a sensing device for sensing capacitance, light, thermal energy, or ultrasonic waves. The tiling device may be a display tiling device or an antenna tiling device. It should be noted that the electronic device may be any combination of the foregoing. In addition, the shape of the electronic device may be rectangular, circular, polygonal, a shape with curved edges, or other suitable shapes.

Reference will now be made in detail to the preferred embodiments of the disclosure, examples of which are illustrated in the accompanying drawings. Wherever possible, the same reference numbers are used in the drawings and the description to refer to the same or like parts.

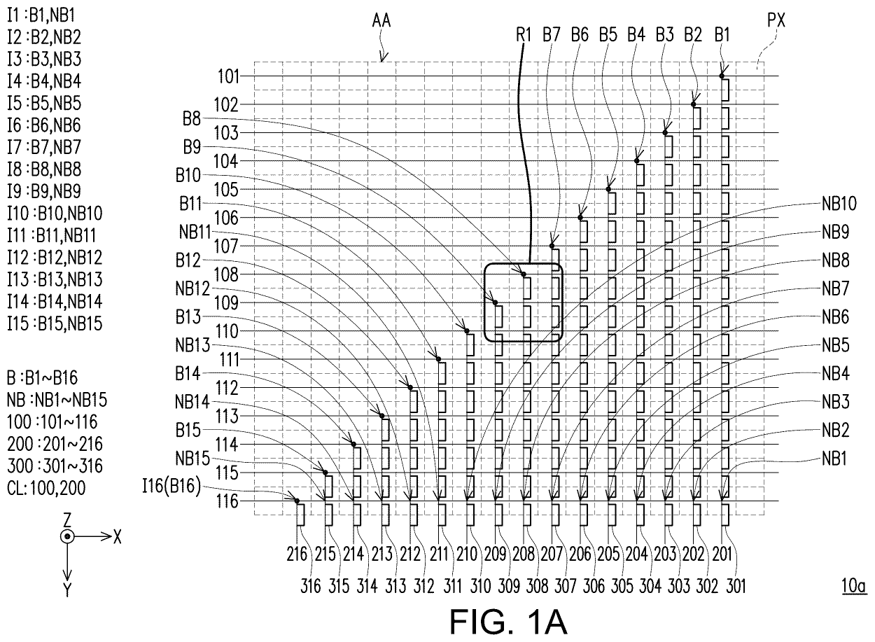

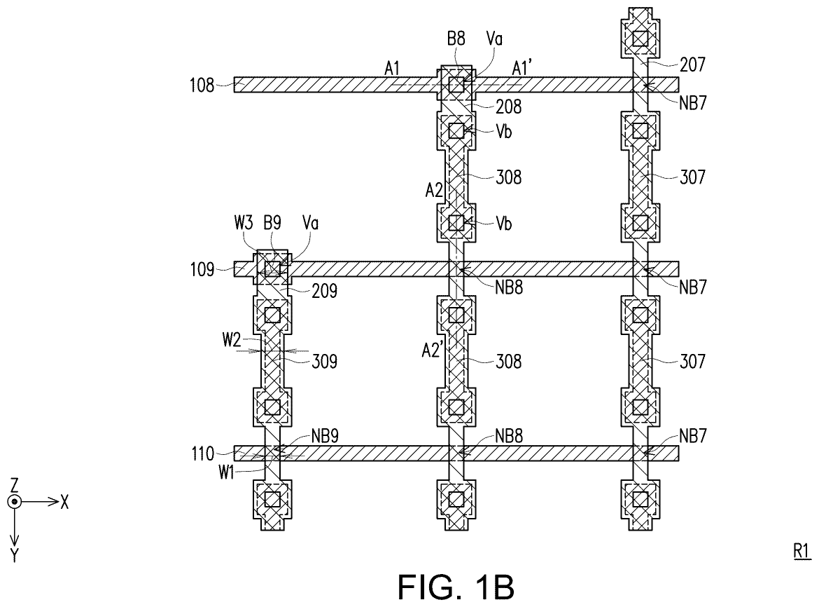

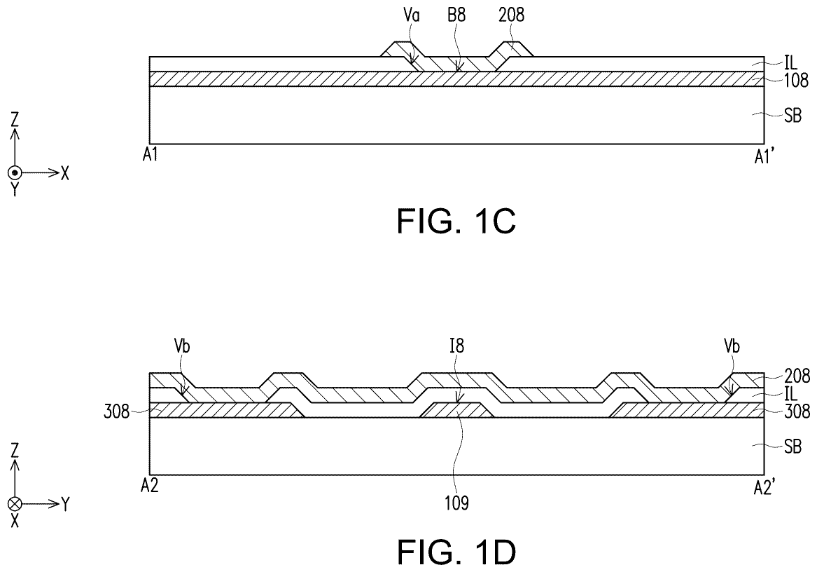

Referring to FIG. 1A to FIG. 1D, an electronic device 10a includes a substrate SB, and the substrate SB has an active area AA and a peripheral area (not shown). In some embodiment, the peripheral area is disposed on one side of the active area AA in a direction Y. The electronic device 10a may be a transparent display device. It should be noted that for clarity of the drawings and convenience of explanation, several components are omitted in FIG. 1A to FIG. 1D.

In the embodiment, the electronic device 10a includes a plurality of scan lines 100, a plurality of scan transmission lines 200, and at least one conductive pattern 300.

In some embodiments, the electronic device 10a may further include a driving component (not shown). The driving component is disposed on the substrate SB and located in the peripheral area. In some embodiments, the driving component may be disposed on the surface of the substrate SB by chip on glass (COG), or by chip on plastic (COP). In other embodiments, the driving component includes a driving circuit and is directly disposed on the surface of the substrate SB (gate on panel; GOP). The driving component may include a driving chip, a circuit board, or a combination thereof. In some embodiments, the driving chip may include a driving unit such as a timing control unit, a data driving unit, and a power driving unit, and the circuit board may include a flexible printed circuit board (FPC), but not limited thereto.

A material of the substrate SB may be, for example, glass, plastic, quartz, sapphire, polymethyl methacrylate (PMMA), polycarbonate (PC), polyimide (PI), polyethylene terephthalate (PET), or other suitable materials, or a combination thereof, but not limited thereto.

The plurality of scan lines 100 are disposed on the active area AA of the substrate SB and are electrically connected to transistors (not shown), in which one of the plurality of scan lines 100 may provide a gate signal to a corresponding transistor. In the embodiment, the plurality of scan lines 100 extend toward a direction X and may include scan lines 101 to 116. In the embodiment, the plurality of scan lines 100 may have substantially the same length with each other in the direction X. In the disclosure, the length of a signal line may be measured along an extending direction of the signal line. The material of the plurality of scan lines 100 may include titanium (Ti), molybdenum (Mo), chromium (Cr), aluminum (Al), copper (Cu), an alloy thereof, other suitable conductive materials, or a combination thereof, and the plurality of scan lines 100 may be a single-layer or multi-layer structure.

The plurality of scan transmission lines 200 are disposed on the active area AA of the substrate SB and are each electrically connected to one of the plurality of scan lines 100. In the embodiment, the plurality of scan transmission lines 200 cross the plurality of scan lines 100, forming a plurality of intersections I. In detail, the intersection I is a position where one of the plurality of scan transmission lines 200 and one of the plurality of scan lines 100 overlap with each other in a direction Z. Based on this, when one of the plurality of scan transmission lines 200 is longer, it will have a larger number of intersections I. For example, the number of the intersections I1 of the scan transmission line 201 and the plurality of scan lines 100 is greater than the number of the intersections 12 of the scan transmission line 202 and the plurality of scan lines 100. A material of the plurality of scan transmission lines 200 may be the same as a material of the plurality of scan lines 100, and the plurality of scan transmission lines 200 may be a single-layer or multi-layer structure.

In the embodiment, the plurality of scan transmission lines 200 extend toward the direction Y and may include scan transmission lines 201 to 216, in which the scan transmission lines 201 to 216 may each form intersections I1 to 116 with the scan lines 101 to 116. The plurality of scan transmission lines 200 may include a first scan transmission line 201 and a second scan transmission line 202, where the first scan transmission line 201 forms a plurality of first intersections I1 with the scan lines 101 to 116, the second scan transmission line 202 forms a plurality of second intersections 12 with the scan lines 101 to 116, and so on. It is worth noting that although FIG. 1A only indicates one intersection I1 to 116, this does not represent that the number of the intersection is only one. In the embodiment, the plurality of intersections I include bridge portions B and non-bridge portions NB, where the bridge portion B is a position where one of the plurality of scan transmission lines 200 is electrically connected to one of the plurality of scan lines 100. Based on this, by electrically connecting the corresponding scan transmission line 200 with the scan line, a signal line CL may be formed. Referring to FIG. 1A, the first intersection I1 includes a first bridge portion B1 where the first scan transmission line 201 is electrically connected to the first scan line 101, and a first non-bridge portion NB1 where the first scan transmission line 201 overlaps with the scan lines 102 to 116, and so on.

In the embodiment, an insulating layer IL is disposed between the plurality of scan lines 100 and the corresponding scan transmission lines 200, where the insulating layer IL has vias Va to enable the plurality of scan transmission lines 200 to be electrically connected to the corresponding scan lines 100 through the bridge portions B. The scan transmission line 208 is electrically connected to the scan line 108 through the via Va of the insulating layer IL, and so on. In some embodiments, a material of the insulating layer IL may include silicon nitride (SiNx), silicon oxide (SiOx), organic material, other suitable insulation materials, or a combination thereof.

In the embodiment, a length of the first scan transmission line 201 is greater than a length of the second scan transmission line 202. The scan transmission lines 201 to 216 may each have progressively shorter lengths in this order, but not limited thereto.

In some embodiments, the scan transmission line 200 has a first width at the intersection I, the scan transmission line 200 has a second width at the non-intersection, and the first width is less than or equal to the second width. In the embodiment, a width W1 of the scan transmission line 209 at the intersection 19 (such as the non-bridge portion NB9) is less than a width W2 at the non-intersection. In some embodiments, a width W3 of scan transmission line 209 at the bridge portion B9 is greater than or equal to the width W1. In this disclosure, a width of a signal line (i.e., line width) may be measured along a direction perpendicular to the extending direction of the signal line. The widths W1 to W3 may be measured along the direction X perpendicular to the extending direction of the scan transmission line 209. In some embodiments, the line width of the scan transmission line 200 is greater than or equal to 2.5 micrometers.

At least one conductive pattern 300 is disposed on the active area AA of the substrate SB and is electrically connected in parallel to at least one of the plurality of scan transmission lines 200 and the plurality of scan lines 100. In the embodiment, the at least one conductive pattern 300 and the plurality of scan transmission lines 200 belong to different layers, and are electrically connected in parallel to the corresponding scan transmission line 200, and the at least one conductive pattern 300 may include a plurality of conductive patterns 301 to 316 arranged in the direction Y. The at least one conductive pattern 300 includes a plurality of first conductive patterns 301 and a plurality of second conductive patterns 302. The plurality of first conductive patterns 301 are separated from each other in the direction Y, and at least partially overlap with the first scan transmission line 201 in the direction Z. The plurality of second conductive patterns 302 are separated from each other in the direction Y, and at least partially overlap with the second scan transmission line 202 in the direction Z. In this disclosure, “at least partially overlap” includes partially overlapping or completely overlapping with each other in the direction Z. The setting relationship between the plurality of conductive patterns 303 to 316 and the scan transmission lines 203 to 216 may be inferred by analogy accordingly. A material of the at least one conductive pattern 300 may be the same as a material of the plurality of scan lines 100.

In this disclosure, a minimum distance between patterns formed by the same conductive layer may be greater than or equal to 2.5 micrometers. Since the at least one conductive pattern 300 and the scan line 100 are made from the same conductive layer, a minimum distance between the conductive pattern 300 and the scan line 100 may be greater than or equal to 2.5 micrometers.

In this disclosure, in the top view direction, an edge of the at least one conductive pattern 300 is misaligned with an edge of the scan transmission line 200, and a misalignment distance in the direction X is greater than or equal to 1 micrometer, so as to improve the reliability of the electronic device 10a. As shown in FIG. 1B, both side edges of the at least one conductive pattern 307 are retracted inward from both side edges of the scan transmission line 207. In some embodiments, in the top view direction, one side edge of the conductive pattern 300 is retracted inward from one side edge of the scan transmission line 200, and the other side edge of the conductive pattern 300 protrudes outward from the other side edge of the scan transmission line 200. In this disclosure, a width of the at least one conductive pattern 300 and a width of the scan transmission line 200 may be adjusted as needed, and is not limited to FIG. 1B.

In the embodiment, the insulating layer IL further has a plurality of vias Vb, in which at least two vias Vb are disposed between adjacent intersections I for electrically connecting the at least one conductive pattern 300 with the corresponding scan transmission line 200. Referring to FIG. 1B, the scan transmission line 207 may be electrically connected with the conductive pattern 307 through the two via Vb of the insulating layer IL, and so on. It is worth noting that the number of the vias Vb for electrically connecting the conductive pattern 300 with the scan transmission line 200 shown in FIG. 1B is not limited thereto.

Additionally, the conductive pattern 300 and the scan line 100 belong to the same layer.

In the embodiment, the plurality of conductive patterns 301 to 316 each have corresponding total areas. The plurality of first conductive patterns 301 have a first area (i.e., the total area of the plurality of first conductive patterns 301), and the plurality of second conductive patterns 302 have a second area (i.e., the total area of the plurality of second conductive patterns 302). Since the number of the plurality of first conductive patterns 301 arranged in the direction Y is greater than the number of the plurality of second conductive patterns 302 arranged in the direction Y, the first area of the plurality of first conductive patterns 301 will be greater than the second area of the plurality of second conductive patterns 302. The plurality of conductive patterns 301 to 316 may each have progressively smaller areas in this order.

Continuing to refer to FIG. 1A, in some embodiments, the electronic device 10a may include a plurality of pixels PX, in which the plurality of pixels PX are arranged in an array on a plane formed by the direction X and the direction Y. The pixel PX may be the smallest repeating arrangement unit of the active area AA. In some embodiments, the pixel PX may be defined by alternately arranged scan lines and data lines. In some embodiments, one of the plurality of pixels PX may include a suitable circuit area (not shown), in which the circuit area is electrically connected with the corresponding scan line 100, and may include suitable components.

Additionally, in some embodiments, the electronic device 10a may include data lines (not shown), power lines (not shown), light-emitting lines (not shown) and/or other signal lines in addition to including the plurality of scan lines 100 and the plurality of scan transmission lines 200. In some embodiments, an extending direction of the data lines and an extending direction of the power lines are parallel to an extending direction of the scan transmission lines, and an extending direction of the light-emitting lines is parallel to an extending direction of the scan lines.

Additionally, in some embodiments, a width of the plurality of scan lines 100 and the corresponding scan transmission lines 200 at the intersection I (e.g., the non-bridge portion NB) may be less than or equal to a width of the plurality of scan lines 100 and the corresponding scan transmission lines 200 at the non-intersection, and a total value of a width increase of each scan line 100 and corresponding scan transmission line 200 at the non-intersection may be substantially the same, so that each scan line 100 may have impedance values close to each other, but not limited thereto. The width of the scan line 100 (i.e., line width) may be measured along the direction Y perpendicular to the extending direction of the scan line 100. In some embodiments, the line width of the scan line 100 is greater than or equal to 2.5 micrometers.

In the embodiment, by designing the at least one conductive pattern 300 to be stacked and electrically connected in parallel with the plurality of scan transmission lines 200, the impedance values of the plurality of scan transmission lines 200 may be reduced. The scan transmission lines 201 to 216 each have progressively shorter lengths in this order, while the plurality of conductive patterns 301 to 316 correspondingly disposed therewith may also each have progressively smaller areas in this order. Based on this, each signal line CL may have similar resistance-capacitance loadings (RC loading), thereby improving the signal transmission quality of the electronic device 10a.

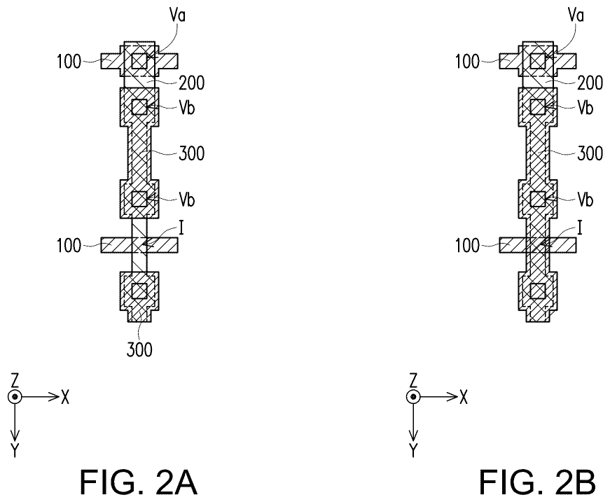

Referring to FIG. 2A, in the embodiment, the at least one conductive pattern 300 and the plurality of scan lines 100 belong to different layers. The at least one conductive pattern 300 is disposed above the plurality of scan lines 100 and the plurality of scan transmission lines 200, in which the plurality of scan transmission lines 200 are disposed between the at least one conductive pattern 300 and the plurality of scan lines 100 in the direction Z.

In the embodiment, a minimum distance between two adjacent conductive patterns 300 and a minimum distance between two adjacent scan lines 100 may be greater than or equal to 2.5 micrometers. In the embodiment, both side edges of the at least one conductive pattern 300 protrude outward from both side edges of the scan transmission line 200, but not limited thereto.

Through such a design, a distance between the at least one conductive pattern 300 and the plurality of scan lines 100 may be increased, thereby further reducing the possibility of generating capacitive load between the at least one conductive pattern 300 and the scan lines 100.

Referring to FIG. 2B, in the embodiment, the at least one conductive pattern 300 and the plurality of scan lines 100 belong to different layers, and the at least one conductive pattern 300 may extend in the direction Y and partially overlap with the plurality of scan lines 100 in the direction Z, that is, may overlap with at least one intersection I.

In some embodiments, the conductive patterns 301 to 316 electrically connected in parallel to the scan transmission lines 201 to 216 may be as shown in FIG. 2B, in which the number of the conductive patterns 301 to 316 is one each, and the conductive patterns 301 to 316 may each have progressively smaller length and area in this order. Since a length of the first conductive pattern 301 in the direction Y is greater than a length of the second conductive pattern 302 in the direction Y, a first area of the first conductive pattern 301 will be greater than a second area of the second conductive pattern 302.

In some embodiments, one scan transmission line 200 is electrically connected in parallel with the conductive patterns 300 shown in both FIG. 2A and FIG. 2B simultaneously, such that the scan transmission line 200 has at least two conductive patterns 300 of different lengths.

Since the plurality of scan transmission lines 200 are disposed between the at least one conductive pattern 300 and the plurality of scan lines 100 in the direction Z, and the scan transmission lines 200 at least partially overlap with the at least one conductive pattern 300 in the direction Z, even though a part of the at least one conductive pattern 300 overlaps with a part of the corresponding scan line 100 in the direction Z, the scan transmission lines 200 may shield the signal coupling between the at least one conductive pattern 300 and the plurality of scan lines 100, thereby further reducing the possibility of generating capacitive load between the at least one conductive pattern 300 and the scan lines 100.

It is worth noting that the setting relationship of the at least one conductive pattern 300, the plurality of scan lines 100, and the plurality of scan transmission lines 200 may be adjusted as needed. In some embodiments, the plurality of scan lines 100 may be disposed above the plurality of scan transmission lines 200 and the at least one conductive pattern 300. Alternatively, in still other embodiments, the plurality of scan lines 100 and the at least one conductive pattern 300 may be disposed above the plurality of scan transmission lines 200, and the plurality of scan lines 100 and the at least one conductive pattern 300 belong to the same layer or different layers.

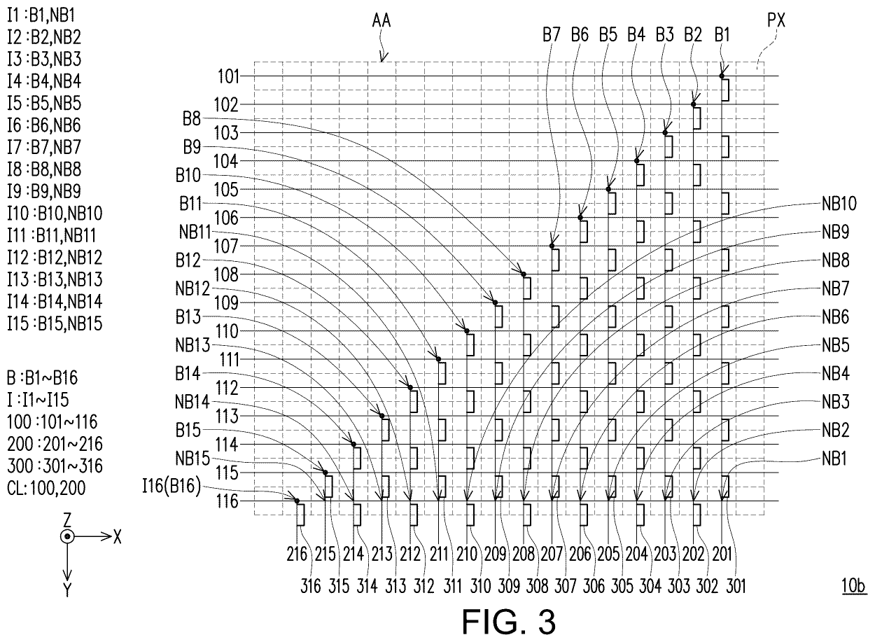

In the embodiment shown in FIG. 3, the at least one conductive pattern 300 electrically connected in parallel with the scan transmission lines 200 in an electronic device 10b is only disposed between part of the intersections I. In other words, the conductive patterns 300 may not be disposed between part of the intersections I.

In the embodiment, the at least one conductive pattern 300 in the electronic device 10b is arranged alternately in the direction X. Taking the conductive patterns 300 located between the scan line 114 and the scan line 116 as an example, the conductive patterns 301 to 316 are arranged alternately in the direction X.

In the embodiment, the at least one conductive pattern 300 in the electronic device 10b is arranged alternately in the direction Y. For example, the conductive pattern 301 and the conductive pattern 302 are arranged alternately in the direction Y.

In some embodiments, segments of the plurality of scan transmission lines 200 that do not overlap with the at least one conductive pattern 300 may overlap with other signal lines.

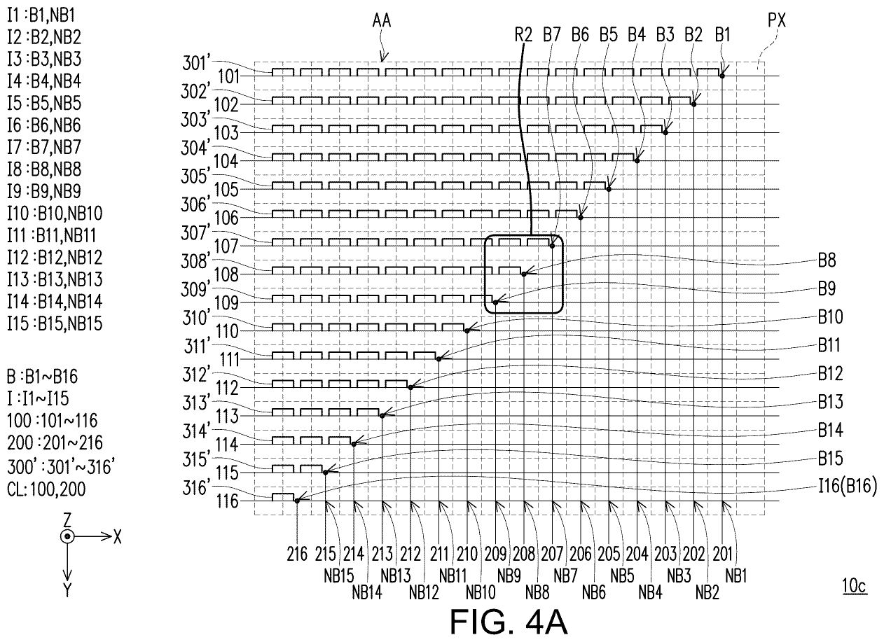

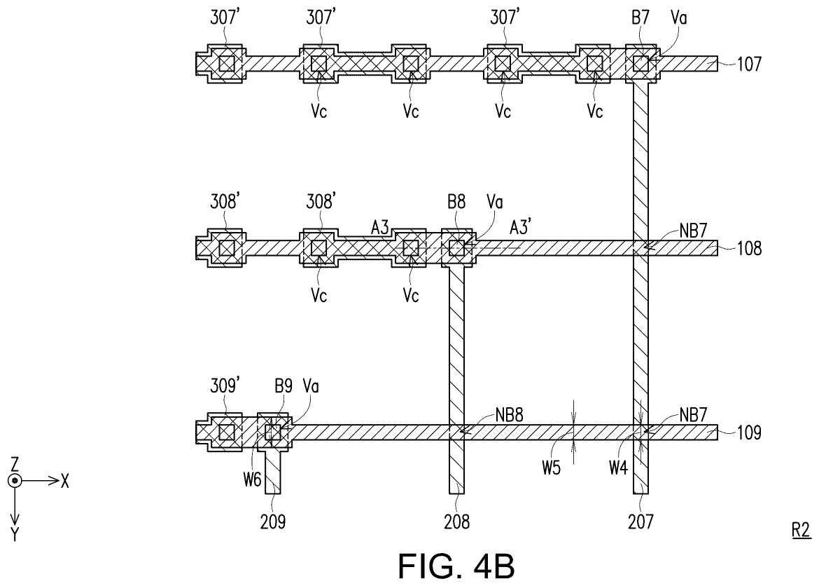

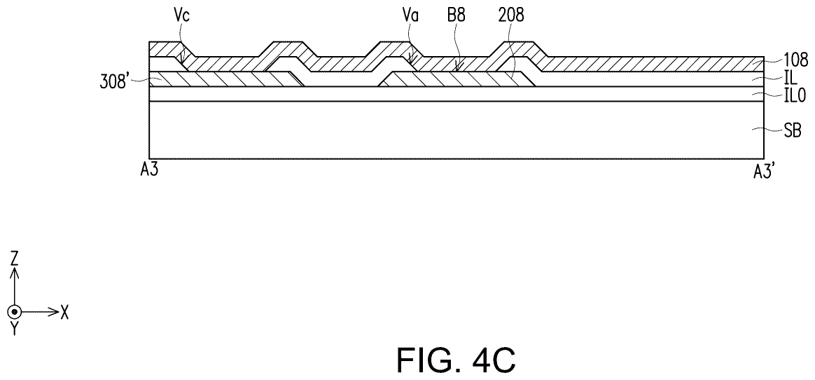

In the embodiment shown in FIG. 4A to FIG. 4C, an electronic device 10c includes at least one conductive pattern 300′.

In the embodiment, the at least one conductive pattern 300′ is electrically connected in parallel to the corresponding scan line 100, and the at least one conductive pattern 300′ may include a plurality of conductive patterns 301′ to 316′ arranged in the direction X. The at least one conductive pattern 300′ may include a plurality of first conductive patterns 301′ and a plurality of second conductive patterns 302′. The plurality of first conductive patterns 301′ are separated from each other in the direction X and at least partially overlap with the first scan line 101 in the direction Z. The plurality of second conductive patterns 302′ are separated from each other in the direction X and at least partially overlap with the second scan line 102 in the direction Z. The setting relationship between the plurality of conductive patterns 303′ to 316′ and the scan lines 103 to 116 may be inferred by analogy accordingly, and therefore repeated description is not provided hereinafter. In the embodiment, the insulating layer IL has a via Vc, so that at least one conductive pattern 300′ may be electrically connected to the corresponding scan line 100 through the corresponding via Vc. Referring to FIG. 4B, the scan line 107 may be electrically connected to the conductive pattern 307′ through the via Vc of the insulating layer IL, and so on. It is worth noting that the number of the vias Vc for electrically connecting the conductive pattern 300′ to the scan line 100 shown in FIG. 4B is not limited thereto. A material of the at least one conductive pattern 300′ may be the same as a material of the plurality of scan lines 100.

In the disclosure, in the top view, an edge of the at least one conductive pattern 300′ is misaligned with an edge of the scan line 100, and a misalignment distance in the direction Y is greater than or equal to 1 micrometer, so as to improve the reliability of the electronic device 10a. As shown in FIG. 4B, both side edges of the at least one conductive pattern 307′ protrude outward from both side edges of the scan line 107. A width of the at least one conductive pattern 300′ and a width of the scan line 100 may be adjusted as needed, and is not limited to FIG. 4B.

In some embodiments, a width W4 of the scan line 109 and the corresponding scan transmission line 207 at the intersection (such as non-bridge portion NB7) may be less than or equal to a width W5 of the scan line 109 at the non-intersection. In some embodiments, a width W6 of the scan line 109 at the bridge portion B9 is greater than or equal to width W4.

In the embodiment, the at least one conductive pattern 300′ and the scan transmission line 200 belong to the same layer. Additionally, the electronic device 10c includes an insulating layer ILO disposed between the at least one conductive pattern 300′ (or scan transmission line 200) and the substrate SB. The plurality of conductive patterns 301′ to 316′ each have a corresponding total area. The plurality of first conductive patterns 301′ have a first area (i.e., the total area of the plurality of first conductive patterns 301′), and the plurality of second conductive patterns 302′ have a second area (i.e., the total area of the plurality of second conductive patterns 302′). In the embodiment, since the number of the plurality of first conductive patterns 301′ arranged in the direction X is greater than the number of the plurality of second conductive patterns 302′ arranged in the direction X, a first area of the plurality of first conductive patterns 301′ is greater than a second area of the plurality of second conductive patterns 302′. The plurality of conductive patterns 301′ to 316′ may each have progressively smaller areas in this order.

In the embodiment, by designing the at least one conductive pattern 300′ to be stacked and be electrically connected in parallel with the plurality of scan lines 100, the impedance values of the plurality of scan lines 100 may be reduced. The scan transmission lines 201 to 216 each have progressively shorter lengths in this order, while the plurality of conductive patterns 301′ to 316′ correspondingly disposed with the scan lines 101 to 116 may also each have progressively smaller areas in this order. Based on this, each signal line CL may have similar RC loading, thereby improving the signal transmission quality of the electronic device 10c.

It is worth noting that the electronic device 10c may be combined with the electronic device 10a or the electronic device 10b, and simultaneously include the at least one conductive pattern 300 and the at least one conductive pattern 300′.

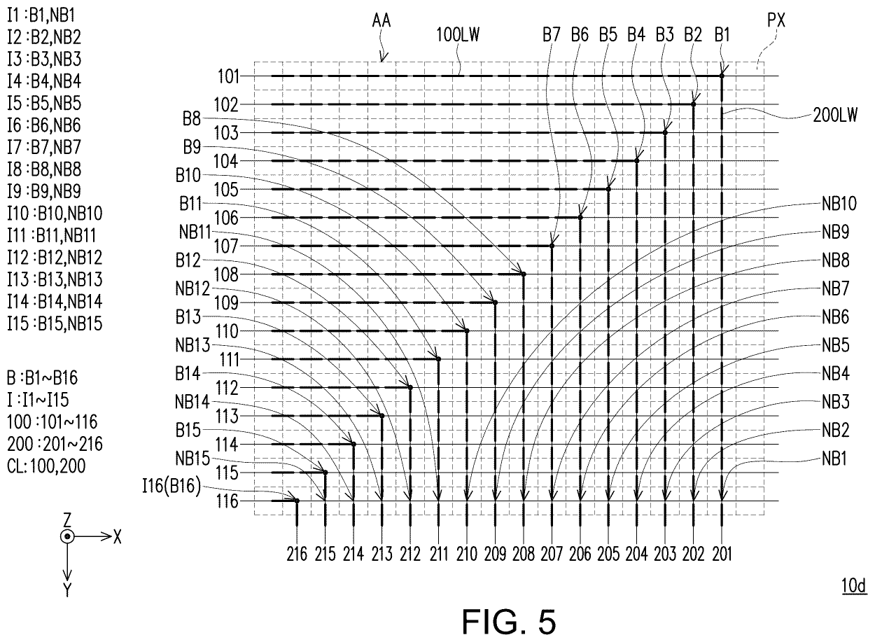

In the embodiment shown in FIG. 5, the plurality of scan lines 100 have a first width at the intersection I, the plurality of scan lines 100 have a second width at the non-intersection, and the first width is less than the second width. The plurality of scan lines 100 have a plurality of widened segments 100LW at the non-intersection, in which the number of the widened segments 100LW that the scan lines 101 to 116 have decreases in this order.

In the embodiment, the plurality of scan transmission lines 200 have a third width at the intersection I, the plurality of scan transmission lines 200 have a fourth width at the non-intersection, and the third width is less than or equal to the fourth width. The plurality of scan transmission lines 200 have a plurality of widened segments 200LW at the non-intersection, in which the number of the widened segments 200LW that the scan transmission lines 201 to 216 have decreases in this order.

In some embodiments, the plurality of scan lines 100 and/or the plurality of scan transmission lines 200 may not have widened segments 100LW or widened segments 200LW at part of the non-intersections, and the non-intersections may overlap other signal lines (e.g., data lines), but not limited thereto.

Through such a design, the impedance values of the plurality of scan lines 100 and/or the plurality of scan transmission lines 200 may be further reduced. Therefore, signal lines CL having a larger number of widened segments 100LW and/or widened segments 200LW may have impedance values that decrease more. Based on this, each signal line CL will have similar RC loading, thereby improving the signal transmission quality of the electronic device 10d.

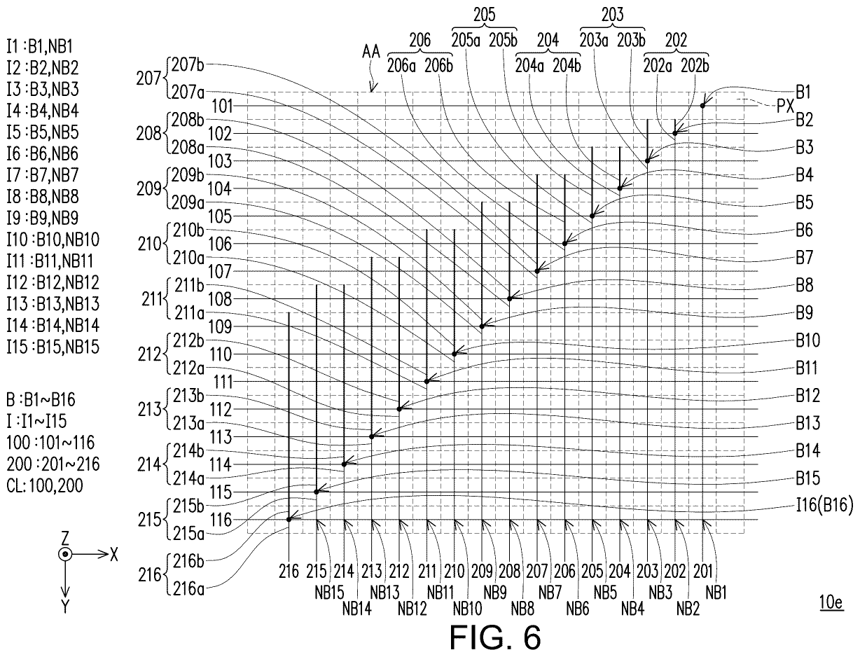

In the embodiment shown in FIG. 6, each of the plurality of scan transmission lines 200 in an electronic device 10e includes a main line 200a and an extension line 200b electrically connected to the main line 200a, and the main line 200a and the extension line 200b are respectively disposed on two different sides of the bridge portion B.

In the embodiment, the plurality of scan transmission lines 200 may include scan transmission lines 201 to 216, in which the scan transmission lines 201 to 216 may respectively form the intersections I1 to 116 with the scan lines 101 to 116. The scan transmission lines 202 to 216 may respectively include main lines 202a to 216a and extension lines 202b to 216b, and the main lines 202a to 216a and the extension lines 202b to 216b are respectively disposed on two different sides of corresponding bridge portions B2 to B16. The plurality of scan transmission lines 200 may include a first scan transmission line 203 and a second scan transmission line 204, a first main line 203a and a first extension line 203b of the first scan transmission line 203 are respectively disposed on two different sides of a first bridge portion B3, and a second main line 204a and a second extension line 204b of the second scan transmission line 204 are respectively disposed on two different sides of a second bridge portion B4. It is worth noting that although the scan transmission line 201 does not include an extension line.

In the embodiment, at least two of scan transmission lines 201 to 216 may have different lengths from each other. The length of the first scan transmission line 203 (or a total length of the first main line 203a and the first extension line 203b) is different from the length of the second scan transmission line 204 (or a total length of the second main line 204a and the second extension line 204b). Additionally, the scan transmission lines 201 to 216 may sequentially have progressively smaller lengths, in which the main lines 202a to 216a may sequentially have progressively smaller lengths, and the extension lines 202b to 216b may sequentially have progressively smaller or equal lengths. A length of the first main line 203a is greater than a length of the second main line 204a, and a length of the first extension line 203b is equal to a length of the second extension line 204b, such that a length of the first scan transmission line 203 may be greater than the length of the second scan transmission line 204. In some embodiments, two adjacent scan transmission lines may, e.g., have substantially equal lengths.

From another perspective, the extension lines 202b to 216b have parts that overlap with the corresponding scan lines 102 to 116 in the direction Z. In the embodiment, the extension lines 202b to 216b may sequentially have progressively more or equal overlapping parts with the corresponding scan lines 102 to 116.

Based on this, by making each of the plurality of scan transmission lines 200 include the main line 200a and the extension line 200b disposed on two different sides of the bridge portion B, although the main lines 202a to 216a sequentially have progressively shorter lengths, the extension lines 202b to 216b correspondingly disposed therewith may have longer or equal lengths. Therefore, each signal line CL will have similar resistance-capacitance loads, thereby improving the signal transmission quality of the electronic device 10e.

It is worth noting that the electronic device 10e may be combined with other embodiments. The electronic device 10e may be combined with the electronic device 10a to simultaneously include the extension lines 200b and the at least one conductive pattern 300.

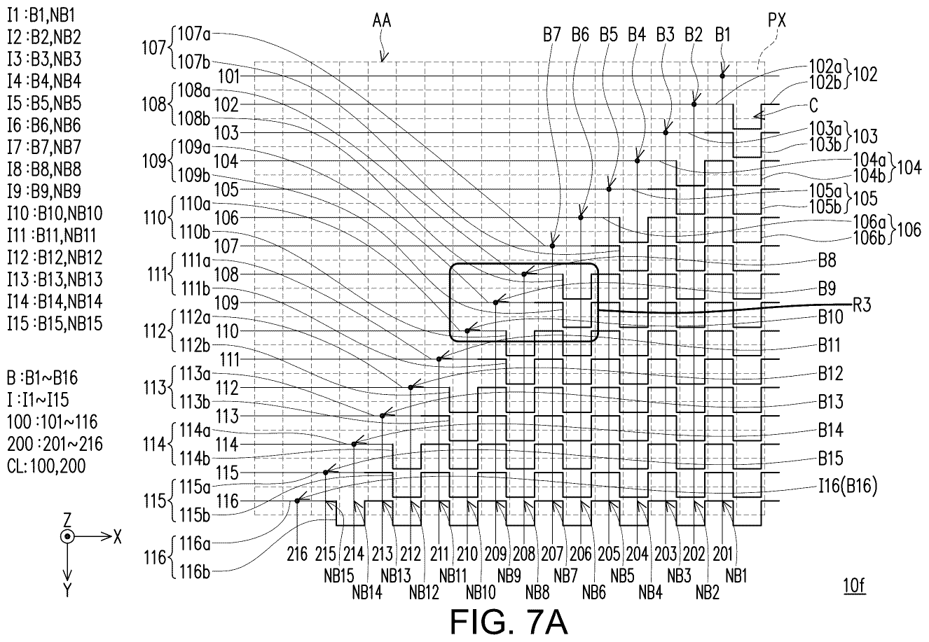

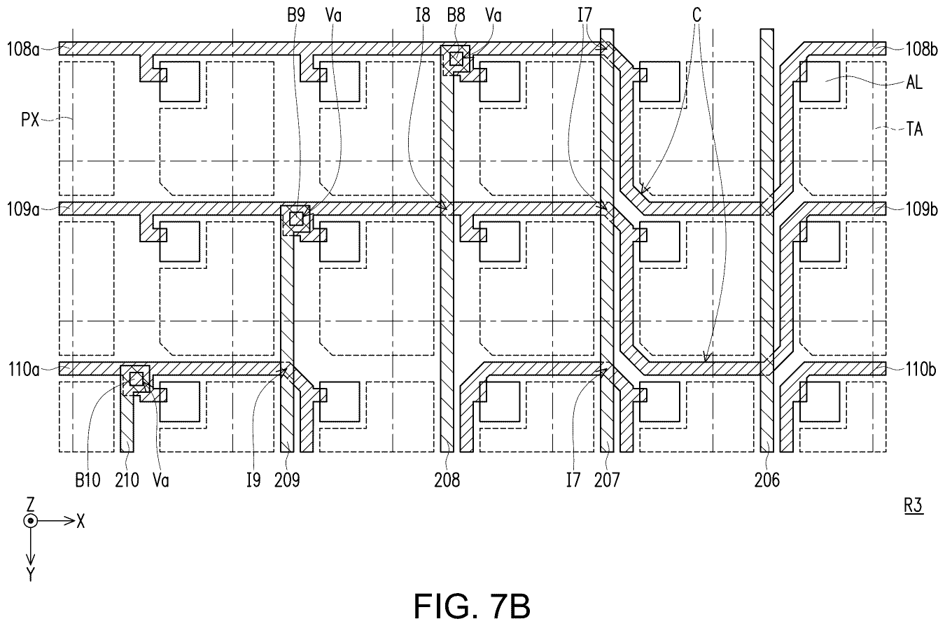

In the embodiment shown in FIG. 7A and FIG. 7B, at least one scan lines 100 in an electronic device 10f has different shapes disposed on two different sides of bridge portion B.

In the embodiment, the plurality of scan lines 100 may include the scan lines 101 to 116, in which the scan lines 102 to 116 each have different shapes disposed on two different sides of the corresponding bridge portions B2 to B16. The scan lines 102 to 116 may each include first portions 102a to 116a and second portions 102b to 116b, and the first portions 102a to 116a and the second portions 102b to 116b are respectively disposed on two different sides of the corresponding bridge portions B2 to B16. The plurality of scan lines 100 includes a first scan line 103 and a second scan line 104, the first portion 103a and the second portion 103b of the first scan line 103 are respectively disposed on two different sides of the first bridge portion B3, and the first portion 104a and the second portion 104b of the second scan line 104 are respectively disposed on two different sides of the second bridge portion B4. In the embodiment, the first portions 102a to 116a are straight line portions, and the second portions 102b to 116b include a plurality of curved portions C. The second portions 102b to 116b may be composed of the straight line portions in the direction X and the straight line portions in the direction Y, and may have relatively long lengths (compared to simple straight line portions). The second portions 102b to 116b may sequentially have progressively more or equal numbers of curved portions C. The number of the curved portions C of the second portion 102b is equal to the number of the curved portions C of the second portion 103b, and the number of the curved portions C of the second portion 103b is greater than the number of the curved portions C of the second portion 104b. It is worth noting that although the scan line 101 does not include a second portion.

Referring to FIG. 7B, in the embodiment, one of the plurality of pixels PX of the electronic device 10f includes a circuit area AL. It is worth noting that although not shown in the above embodiments, the electronic devices 10a to 10e may also include the circuit area AL.

The circuit area AL may include at least one conductive layer (not shown) and at least one insulating layer (not shown). In the embodiment, the circuit area AL is electrically connected to the corresponding scan line 100, and includes non-transmissive or light-transmissive materials or components, such as transistors (not shown), light-emitting components (not shown), or other electronic components (e.g., capacitors, resistors, inductors, diodes, switches, sensors). The light-emitting component may include light-emitting diodes, organic light emitting diodes (OLED), inorganic light emitting diodes (LED), such as mini LEDs or micro LEDs, quantum dots (QD), QDLEDs, fluorescence, phosphor, other suitable materials, or a combination thereof.

In the embodiment, the electronic device 10f further includes a plurality of transparent areas TA, in which at least a part of the transparent area TA may be disposed in the corresponding pixel PX. The transparent area TA may be a region formed by light-transmissive material. The light-transmissive material may include an organic material, an inorganic material, an adhesive material, a filling material, or an encapsulation material. In some embodiments, the transparent area TA may be defined as a region other than the circuit area AL and the signal lines. In the embodiment, one curved portion C of the second portion 108b may accommodate one transparent area TA in the direction Y. In the embodiment, as shown in FIG. 7A, each of the scan lines 102 to 116 includes a plurality of curved portions C that may be arranged in the direction X. In the embodiment, as shown in FIG. 7B, the curved portion C of the scan line 108 and the curved portion C of the scan line 109 are arranged in the direction Y, thereby reducing the possibility that the area of the transparent area TA is reduced due to the setting of the curved portion C.

Based on this, in the embodiment, by making the scan lines 102 to 116 each include the second portions 102b to 116b having a plurality of curved portions C, and making the second portions 102b to 116b sequentially have increasingly more or equal numbers of the curved portions C, the scan lines 102 to 116 may have longer or equal lengths in this order, so as to have larger or equal impedance values. Therefore, each signal line CL will have similar RC loading, thereby improving the signal transmission quality of the electronic device 10f.

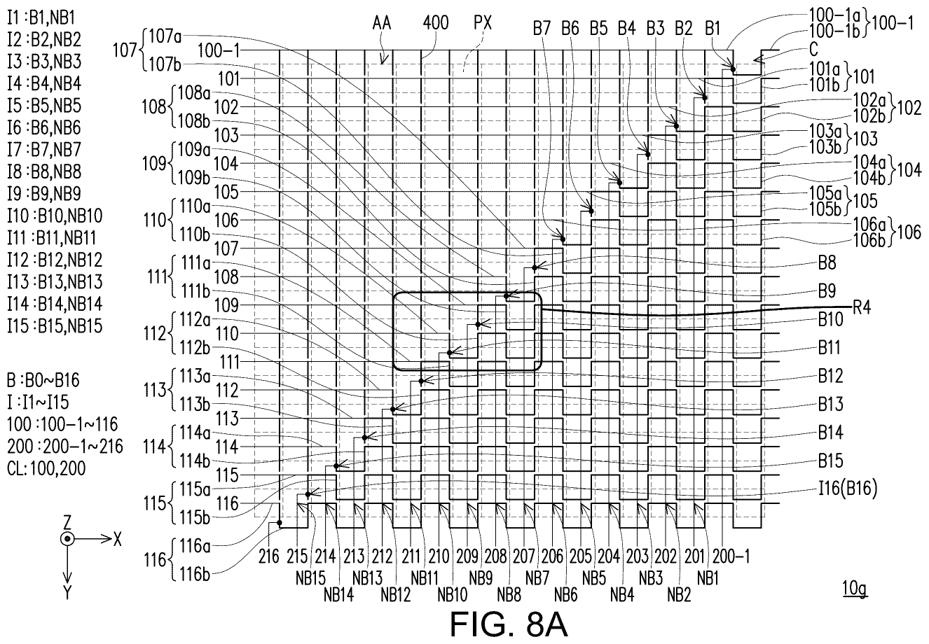

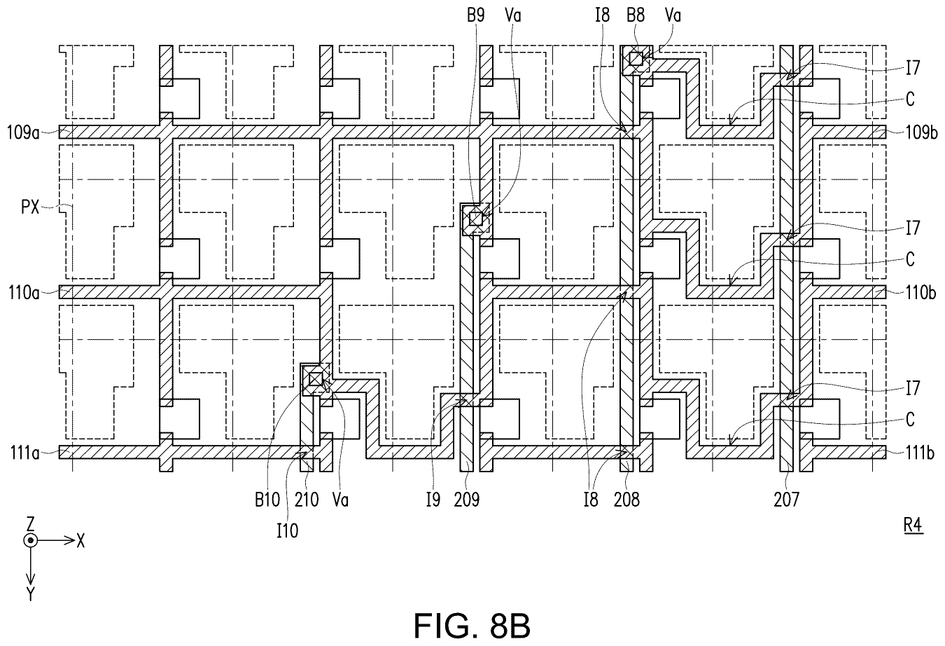

In the embodiment shown in FIG. 8A to FIG. 8B, the main difference between an electronic device 10g and electronic device 10f lies in that: the circuit area AL within one pixel PX may receive signals from two adjacent scan lines 100.

The electronic device 10g may further include a scan line 100-1, a scan transmission line 200-1, and an extension line segment 400. In the embodiment, the adjacent scan line 100-1 and scan line 101 may each provide the same or different signals to the circuit area AL within the first row of pixels PX. By analogy, the adjacent scan line 115 and scan line 116 may each provide the same or different signals to the circuit area AL within the sixteenth row of pixels PX, and therefore repeated description is not provided hereinafter. The extension line segment 400 is electrically connected to the first portions 100a to 116a of the corresponding scan line 100. In the embodiment, the extension line segment 400 extends along the direction Y and is electrically connected to the circuit area AL within the corresponding pixel PX. The extension line segment 400 electrically connected to the scan line 100-1 extends along the direction Y and is electrically connected to the circuit area AL within the first row of pixels PX.

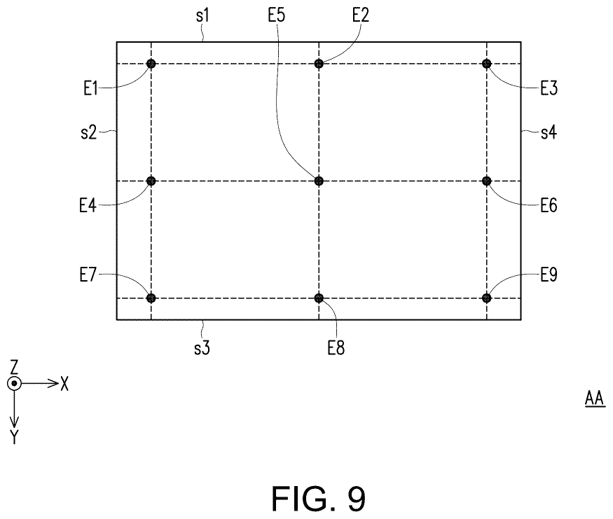

The embodiment shown in FIG. 9 illustrates a method for luminance measurement of the electronic device 10. In detail, nine endpoints E1 to E9 may be selected to measure the uniformity of the electronic device 10. The endpoints E2, E5, and E8 are located at approximately midpoint of the active area AA along the direction X. The endpoints E4, E5, and E6 are located at approximately midpoint of the active area AA along the direction Y. The endpoints E1, E2, E3, E4, E6, E7, E8, and E9 are each close to at least one edge of the active area AA. Specifically, for any endpoint closed to an edge, its distance to the edge is approximately 1/10th of the distance between the edge and the opposite edge of the active area AA. For example, a distance of the endpoint E1 to the edge s1 is approximately 1/10th of the distance between the edge s1 and the edge s3, and a distance of the endpoint E9 to the edge s4 is approximately 1/10th of the distance between the edge s4 and the edge s2, and so on.

In some embodiments, a spectrophotometer may be used to measure the luminance values of the nine endpoints (e.g., endpoints E1 to E9) to calculate the luminance uniformity of the electronic device 10. The uniformity of the corresponding region of the electronic device 10 may be defined as a luminance value percentage between the endpoint having the minimum luminance value among the nine endpoints and the endpoint having the maximum luminance value among the nine endpoints. In the embodiment, the luminance uniformity of the electronic device 10 is greater than or equal to 75%. It is worth noting that the method for luminance measurement of the electronic device 10 may be applied to the electronic devices 10a to 10g.

In summary, the electronic device provided by the various embodiments of the disclosure allow each signal line will have similar RC loading, thereby improving the signal transmission quality of the electronic device. Therefore, the image quality of the electronic device provided by the embodiments of the disclosure can be improved.

What is claimed is:

1. An electronic device, comprising:
a plurality of scan lines, comprising a first scan line and a second scan line;
a first scan transmission line, crossing the plurality of scan lines to form a plurality of first intersections, wherein the plurality of first intersections comprise a first bridge portion where the first scan transmission line is electrically connected to the first scan line;
a second scan transmission line, crossing the plurality of scan lines to form a plurality of second intersections, wherein the plurality of second intersections comprise a second bridge portion where the second scan transmission line is electrically connected to the second scan line;
at least one first conductive pattern, electrically connected in parallel to at least one of the first scan transmission line and the first scan line, and having a first area; and
at least one second conductive pattern, electrically connected in parallel to at least one of the second scan transmission line and the second scan line, and having a second area,
wherein a length of the first scan transmission line is greater than a length of the second scan transmission line, and the first area is greater than the second area.

2. The electronic device according to claim 1, wherein a number of the plurality of first intersections is greater than a number of the plurality of second intersections.

3. The electronic device according to claim 1, wherein the at least one first conductive pattern is electrically connected to the first scan transmission line through at least two conductive vias, and adjacent ones of the at least two conductive vias are disposed between adjacent ones of the plurality of first intersections in a top view direction.

4. The electronic device according to claim 3, wherein the at least one first conductive pattern overlaps with at least one of the plurality of first intersections in the top view direction.

5. The electronic device according to claim 1, wherein the electronic device has a luminance uniformity greater than or equal to 75%.

6. The electronic device according to claim 1, wherein the at least one first conductive pattern at least partially overlaps with the first scan transmission line in a top view direction, and the at least one second conductive pattern at least partially overlaps with the second scan transmission line in the top view direction.

7. The electronic device according to claim 6, wherein in the top view direction, an edge of the at least one first conductive pattern is misaligned with an edge of the first scan transmission line, and an edge of the at least one second conductive pattern is misaligned with an edge of the second scan transmission line.

8. The electronic device according to claim 1, wherein the at least one first conductive pattern at least partially overlaps with the first scan line in a top view direction, and the at least one second conductive pattern at least partially overlaps with the second scan line in the top view direction.

9. The electronic device according to claim 8, wherein in the top view direction, an edge of the at least one first conductive pattern is misaligned with an edge of the first scan line, and an edge of the at least one second conductive pattern is misaligned with an edge of the second scan line.

10. The electronic device according to claim 1, further comprising a substrate, wherein the substrate comprises an active area and a peripheral area, the plurality of scan lines, the first scan transmission line, the second scan transmission line, the at least one first conductive pattern, and the at least one second conductive pattern are disposed in the active area, and the peripheral area is disposed on one side of the active area.

11. An electronic device, comprising:
a plurality of scan lines, comprising a first scan line and a second scan line;
a first scan transmission line, crossing the plurality of scan lines to form a plurality of first intersections, and comprising a first main line and a first extension line electrically connected to the first main line, wherein the plurality of first intersections comprise a first bridge portion where the first scan transmission line is electrically connected to the first scan line, and the first main line and the first extension line are respectively disposed on two different sides of the first bridge portion in a top view direction; and
a second scan transmission line, crossing the plurality of scan lines to form a plurality of second intersections, and comprising a second main line and a second extension line electrically connected to the second main line, wherein the plurality of second intersections comprise a second bridge portion where the second scan transmission line is electrically connected to the second scan line, and the second main line and the second extension line are respectively disposed on two different sides of the second bridge portion in the top view direction,
wherein a length of the first main line is greater than a length of the second main line, a length of the first extension line is less than or equal to a length of the second extension line, and a length of the first scan transmission line is different from a length of the second scan transmission line.

12. The electronic device according to claim 11, wherein the plurality of scan lines extend along a first direction and have a same length in the first direction, the first scan transmission line and the second scan transmission line extend along a second direction, and the length of the first scan transmission line is greater than the length of the second scan transmission line in the second direction.

13. The electronic device according to claim 11, wherein the electronic device has a luminance uniformity greater than or equal to 75%.

14. The electronic device according to claim 11, further comprising:
at least one first conductive pattern, electrically connected in parallel to at least one of the first scan transmission line and the first scan line, and having a first area; and
at least one second conductive pattern, electrically connected in parallel to at least one of the second scan transmission line and the second scan line, and having a second area,
wherein the first area is greater than the second area.

15. An electronic device, comprising:
a plurality of scan lines, comprising a first scan line; and
a first scan transmission line, crossing the plurality of scan lines to form a plurality of first intersections, wherein the plurality of first intersections comprise a first bridge portion where the first scan transmission line is electrically connected to the first scan line,
wherein shapes of the first scan line disposed on two different sides of the first bridge portion are different in a top view direction.

16. The electronic device according to claim 15, wherein the electronic device has a luminance uniformity greater than or equal to 75%.

17. The electronic device according to claim 15, wherein the first scan line comprises a first portion and a second portion located on two different sides of the first bridge portion, the first portion is a straight line portion, and the second portion comprises a plurality of curved portions.

18. The electronic device according to claim 17, further comprising:
a circuit area, electrically connected to the first scan line; and
a transparent area, wherein at least a part of the transparent area is accommodated by one of the plurality of curved portions.

19. The electronic device according to claim 18, wherein the circuit area receives signals from two adjacent scan lines.

20. The electronic device according to claim 18, wherein the circuit area comprises a transistor and a light-emitting component.
